(19) United States
(12) Patent Application Publication
(10) Pub. No.: US 2009/0103267 A1
(43) Pub. Date: Apr. 23, 2009

(54) ELECTRONIC ASSEMBLY AND METHOD FOR MAKING THE ELECTRONIC ASSEMBLY

(76) Inventors: Andrew Dean Wieland, Forgo, ND (US); Jeffrey Scott Duppong, Fargo, ND (US)

Correspondence Address: DEERE & COMPANY, ONE JOHN DEERE PLACE, MOLINE, IL, 61265, US

(21) Appl. No.: 11/873,495

(22) Filed: Oct. 17, 2007

(51) Int. Cl. H05K 7/20; H05K 3/30

(52) U.S. Cl. 361/707; 29/834; 361/704

(57) ABSTRACT

An electronic assembly comprises a generally planar substrate. An electronic component is mounted to the substrate and has a projecting portion projecting above a surface of the substrate. An enclosure has at least one side with indentations. One of the indentations is positioned to receive the projecting portion of the electronic component with a clearance gap. A thermally-conductive material is inserted between the projecting portion and the enclosure within the clearance gap.

### FIELD OF THE INVENTION

The present invention relates to an electronic assembly and a method for making the electronic assembly.

### BACKGROUND OF THE INVENTION

Electronic assemblies for use in harsh environments or use on mobile equipment require suitable performance despite exposure to vibration and thermal stress during operation. For example, thermal stress may be exacerbated by heat generated by high-power electronic components of the electronic assembly. Thus, there is a need for an electronic assembly and a method for making the electronic assembly that increases thermal dissipation of the electronic assembly while minimizing the stress placed on the electronic components of the electronic assembly.

### SUMMARY OF THE INVENTION

In accordance with one embodiment, an electronic assembly comprises a generally planar substrate. An electronic component is mounted to the substrate and has a projecting portion projecting above a surface of the substrate. An enclosure has at least one side with indentations. One of the indentations is positioned to receive the projecting portion of the electronic component with a clearance gap. A thermally-conductive material, or a precursor thereto, is inserted, placed or dispensed between the projecting portion and the enclosure within the clearance gap.

### BRIEF DESCRIPTION OF THE DRAWINGS

FIG. 1 is a perspective and cross-sectional view of an electronic assembly showing how a substrate with electronic components interfaces to an outer enclosure with indentations.

FIG. 2 shows a circular portion of FIG. 1 in greater detail than FIG. 1 does.

FIG. 3 is an exploded perspective view of the electronic assembly of FIGS. 1 and 2, showing the indentations.

FIG. 4 is an alternate exploded perspective view of the electronic assembly.

FIG. 5 is a flowchart showing a method for making the electronic assembly.

### DESCRIPTION OF THE PREFERRED EMBODIMENT

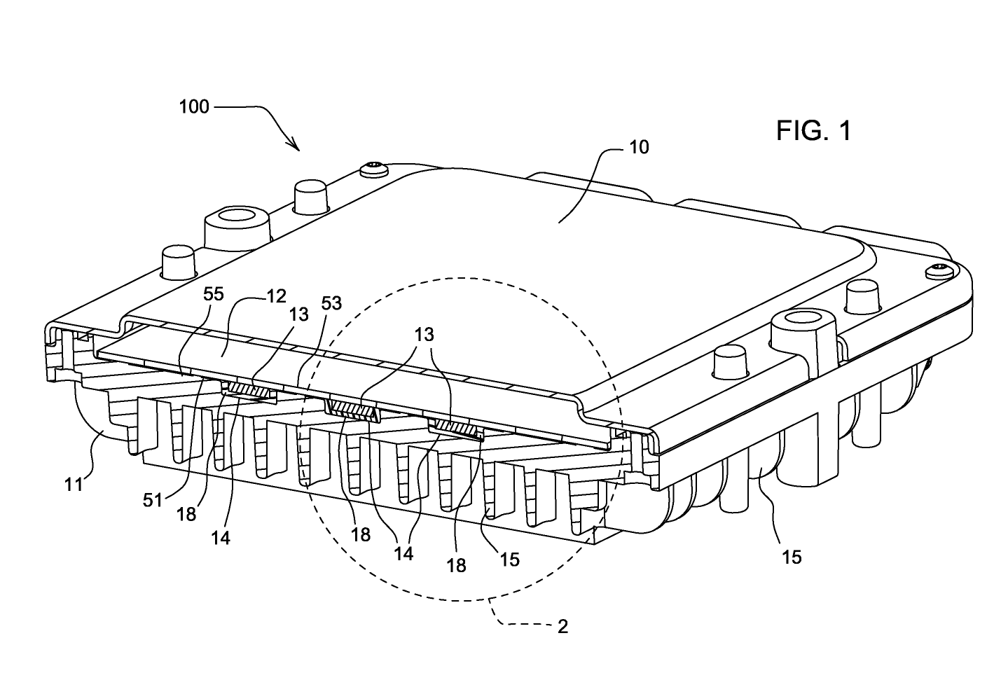

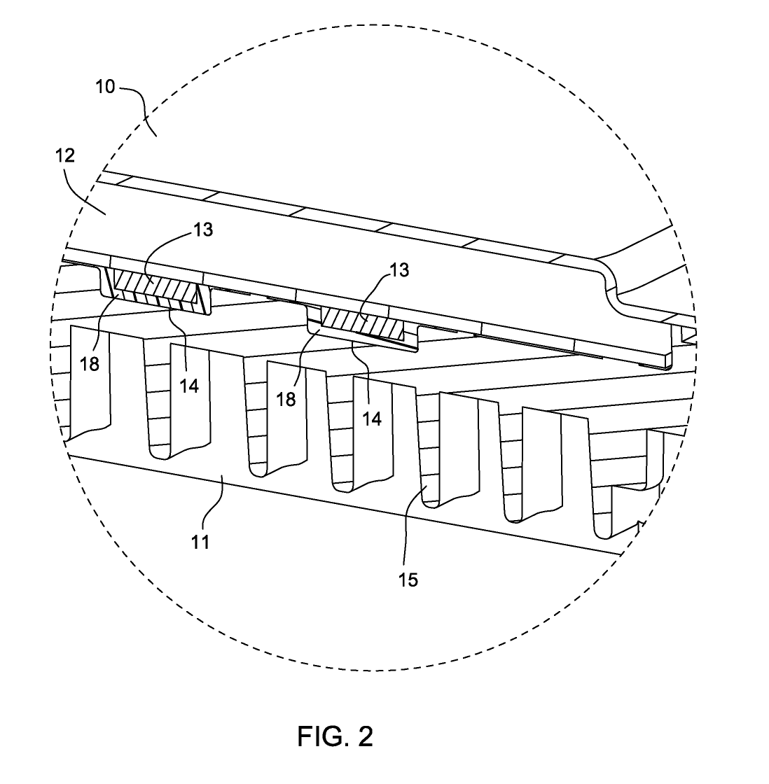

Referring to FIG. 1 and FIG. 2, an electronic assembly 100 (e.g., an electronic control unit) comprises a generally planar substrate 12 (e.g., a printed circuit board). One or more electronic components 13 are mounted to the substrate 12 and have a projecting portion projecting above or from a surface or side (51 or 53) of the substrate 12. An enclosure 11 has at least one side with indentations 14. One of the indentations 14 is positioned to receive the projecting portion of the electronic component 13 with a clearance gap. A thermally-conductive material 18, or a precursor thereto, is inserted, placed or dispensed between the projecting portion and the enclosure 11 within the clearance gap.

The substrate 12 may comprise a ceramic circuit board, fiberglass circuit board, plastic sheet, polymeric substrate, a flexible polymeric substrate, or another suitable dielectric substrate for an electrical circuit. At least a portion of the first side of the substrate 12 is secured (e.g., bonded) directly to the interior surface of an enclosure 11 by a thermally-conductive material 18, a fastener, a connector (e.g., snap-fit connector) or otherwise.

The electronic components 13 may comprise semiconductors, transistors, integrated circuits, discrete components, microprocessors, digital logic circuits, memory, active components, passive components, resistors, capacitors, diodes, transformers, inductors, optical components, and any other electrical or electronic parts. For example, the electronic components 13 may comprise heat-generating power electronics, such as metal-oxide semiconductor, field-effect transistors (MOSFET's) or insulated gate bipolar transistors.

In one embodiment, an electronic component 13 is electrically and mechanically attached (e.g., via solder joints) to a corresponding mounting pad, terminal, conductive trace, plated via, conductive through-hole, connectors, or conductors associated with a first side 51 of the substrate 12. A second side 53 of the substrate 12 is opposite of the first side 51.

In an alternative embodiment, an electronic component 13 is electrically and mechanically attached (e.g., via solder joints) to a corresponding mounting pad, terminal, conductive trace, plated via, conductive through-hole, connectors, or conductors associated with the first side 51, the second side 53, or both sides of the substrate 12.

In one implementation, the enclosure 11 comprises a heat sink (e.g., a heat sink with fins) to provide a potential thermal pathway for heat generated by one or more electronic components 13 to flow through the enclosure 11 and out into the ambient environment (e.g., air), where there is a temperature gradient between the enclosure 11 and the ambient environment. The electronic components 13 extend into one or more indentations 14 which are spatially located in the enclosure 11 such that the components 13 do not interfere with the bonding of at least a portion of the substrate 12 or the first side 51 to the enclosure 11.

In one embodiment, thermally conductive material 18 is composed of an elastomer, a polymer, a resin or a matrix and a thermally conductive filler. For example, the thermally conductive material 18 may be composed of a polymeric resin and a thermally conductive filler, where the filler is a ceramic, a ceramic compound, boron nitride, silicon carbide, alumina, graphite, or the like.

In another embodiment, the thermally conductive material comprises an adhesive or a thermally conductive adhesive (e.g., silicone) that has been impregnated or mixed with ceramic fillers to enhance its thermal conductivity. One example of a commercially-available thermal adhesive is LOCTITE 5406 Thermally Conductive Silicone, but other thermally conductive materials fall within the scope of the disclosure and claims.

In general, a material qualifies as a thermally conductive material 18, if it has a thermal conductivity of greater than or equal to approximately 0.75 Watts per milliKelvin (W/mK), regardless of its composition. Although the thermally conductive material is generally a dielectric material or composition, in alternate embodiments an electrically conductive, thermally conductive material (e.g., thermally conductive grease) may be used, where the enclosure 11, packaging of the component 13, and the substrate 12 are configured or coated with a dielectric barrier, coating or layer to prevent electrical shorts.

The indentations 14 are at least partially filled with a thermally-conductive material 18, or a precursor thereto, before the substrate 12 is placed onto, combined with, or merged with the enclosure 11. A precursor to the thermally-conductive material 18 may comprise one more uncured components or constituents in liquid or flowable form that cure or set after they are mixed, exposed to air, ultraviolet light, or a chemical catalyst. Although the thermally-conductive material 18 may attain or exist in a cured state, a semi-rigid form, a rigid form, a flexible state, a cross-linked state, or generally solid state; in an alternative embodiment the thermally-conductive material 18 remains in a gel-like, foamy, oily, greasy or liquid state. In any case, the substrate 12 is placed to engage an inner surface 55 of the enclosure 11 and electronic components 13 are placed into the indentations 14.

The thermally-conductive material 18 located in the indentations 14 may be displaced, compressed, or contacted as the electronic components 13 extend into the indentations 14. In one embodiment, the thermally-conductive material 18 may flow, migrate or move so that it partially, substantially or completely surrounds the electronic components 13, except where the flow may be restricted (e.g., on the side of the component 13 that is attached to or faces the substrate 12). The flow or migration of the thermally conductive material 18 may be enhanced, hastened, assisted, or caused by application of mechanical force, hydraulic force, injection molding, gravity, or pressure, or other manufacturing procedures. In one embodiment, the thermally conductive material 18 may cure (e.g., by cross-linking of a polymeric matrices) and bond the one or more components 13 to the indentations 14.

The thermally-conductive material 18 partially surrounds, substantially surrounds, or completely surrounds or fills the electronic components 13 to provide a potential thermal path for heat dissipation. “Substantially surrounds” or “substantially fills or filled” means that the thermally conductive material 18 occupies a volume equal to a greater than ninety percent of the volume of any previous gap or clearance bounded by at least two of the following: the component 13, the indentations 14, and the substrate 12. If the thermally conductive material 18 is in a cured state, a semi-rigid form, a rigid form, a flexible state, a cross-linked state, or generally solid state, the thermally-conductive material 18 prevents the movement of the electronic component 13 in relation to the substrate 12, thereby reducing the amount of stress placed on solder joints holding the electronic components 13 to the substrate 12 (e.g., from vibration or external shock).

During operation, the heat generated by the electronic components 13 may flow from the electronic components 13, out through the thermally-conductive material 18, into the enclosure 11. The heat entering the enclosure 11 in this manner is generally radiated in to the ambient environment or open air surrounding the outside of the electronic assembly 100 through mechanical projections 15 such as fins that are molded into or attached to the enclosure 11. The combination of the enclosed 11 and the mechanical projections 15 (or projecting members) may be regarded as an integral heat sink.

In an alternate embodiment, the mechanical projections 15 may be omitted and the enclosure 11 may be composed of a metal, an alloy, or another thermally conductive material of sufficient mass to dissipate the thermal load provided by the operation of the electronic components over an anticipated duty cycle (e.g., a continuous or intermittent duty cycle).

The indentations 14 in the enclosure 11 are sized and shaped such that they are slightly larger than the corresponding electronic components 13 and such that indentations 14 receive the components 13 with a mechanical clearance or air gap for the thermally conductive material 18 in one or more spatial dimensions (e.g., depth, width and height). The thermally-conductive material 18 placed, inserted, or dispensed in the indentations 14 flows or is moved around the electronic components 13 when they are put in position, providing a reliable thermal path from one or more thermally communicating sides of the electronic components 13 to the enclosure 11. In one embodiment, the bonding of the electronic components 13 to the enclosure 11 through the thermally-conductive material 18 that substantially surrounds the electronic components 13 facilitates generally efficient thermal transfer or maximization of the amount of surface area conducting heat away from the electronic components 13.

The electronic components such as high-power electronics are placed on the substrate such that they engage, envelope or contact cured the thermal adhesive. Heat generated by these components is transmitted to the housing, casing or heat sink via the thermal adhesive or other thermally conductive material. Requiring the heat to be pulled through the substrate causes the substrate to become a bottleneck for thermal flow. Because of this bottleneck, heat is not dissipated quickly enough and the temperature of the components may rise too much, reducing component life and reliability.

In one embodiment, one side (51 or 53) or a portion of one side (51 or 53) of a substrate 12 is bonded directly to the enclosure 11 using a thermally-conductive material 18. Some of the electronic components 13 are typically mounted on the second side 53 of the substrate 12, directly opposite the side that is bonded to the enclosure 11. However, electronic components 13 that tend to generate a certain threshold amount of heat can be placed on the side of the substrate 12 that faces or is bonded to the enclosure 11. The foregoing placement of the electronic components 13 is particularly advantageous for power electronics that generate significant heat, where the enclosure 11 is associated with an integral heat sink. The electronic components 13 are placed on the substrate 12 such that they correspond with indentations 14 or pockets built into the enclosure 11. The indentations 14 are slightly larger than the electronic components 13 by an air gap or clearance. The indentations 14 are partially, completely or substantially surrounded or filled with thermally-conductive material 18. If the substrate 12 comes in contact with the enclosure 11 during the bonding process, the electronic components 13 extend into or project into the indentations 14, allowing that side, or a least a portion of the substrate 12, to make direct contact with the enclosure 11. The electronic component may be completely, partially or substantially encased in thermally-conductive material. The adjoining or encasing thermally-conductive material 18 provides a path for heat to flow directly from the component 13 into the enclosure 11 (e.g., metal enclosure 11), where it is then radiated into open air or the ambient environment.

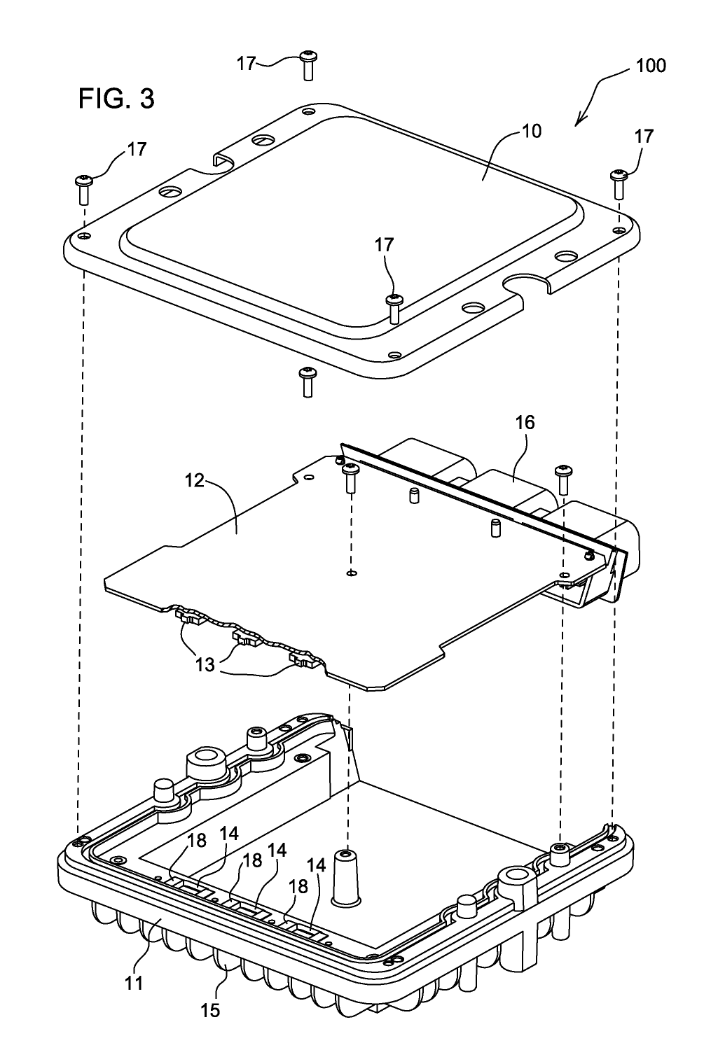

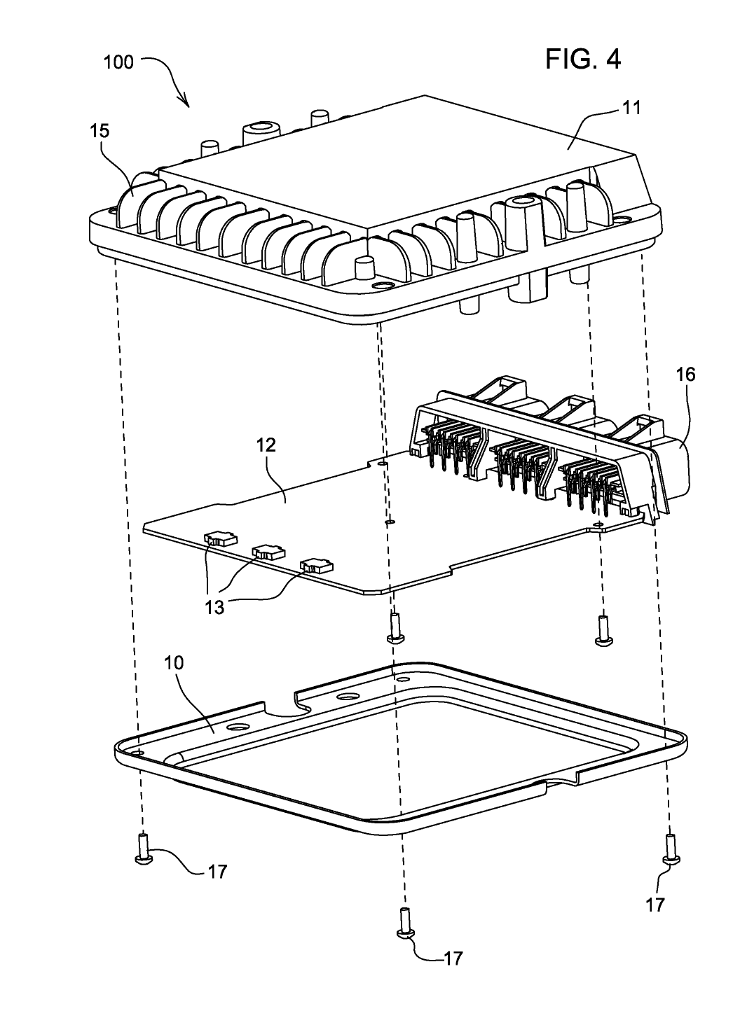

FIG. 3 and FIG. 4 provide alternate exploded views of the electronic assembly 100 of FIG. 1. An enclosure cover 10 can be placed on the electronic assembly 100 and attached to the enclosure 11 with fasteners 17. The enclosure cover 10 attaches to the enclosure 11 and provides an environmental seal (e.g., water resistant, hermetic or otherwise) for the substrate 12 and electronic components. In one embodiment, the enclosure cover 10 and the enclosure 11 may be associated with an intervening seal or gasket that is interposed between the enclosure cover 10 and the enclosure 11 to form a water-resistant or hermetic seal. The combination of the enclosure cover 10, the enclosure 11, and the seal generally protect the substrate 12 and electronic components 13 from the external environment, shock, vibration, humidity, salt-fog, rain, precipitation, or other environmental factors.

The enclosure 11 comprises one or more mechanical features 15 such as fins, ribs or similar extensions. In one configuration, the mechanical features 15 increase the outer surface area of the enclosure 11 such that the flow of heat out from the electronic assembly 100 can be enhanced or maximized.

The enclosure 11 comprises one or more indentations 14 which are molded into the interior of the enclosure 11. These indentations 14 are located in an interior surface of the enclosure 11 such that they are co-located or registered with corresponding electronic components 13 on one side (e.g., bottom side) of the substrate 12. The indentations 14 and the surrounding surface of the enclosure 11 are coated, filled, or injected with a thermally-conductive material 18, which provides a thermal path for heat to migrate from the electronic components 13 to the enclosure 11. In one embodiment, one or more electrical connectors 16 are attached to the substrate 12 to provide electrical connections with electronic assemblies, systems, conductors, cables, wiring harnesses, or otherwise.

After the substrate 12 is placed onto the thermally-conductive material 18 inside the enclosure 11, the enclosure cover 10 is put in place on top of the enclosure 11 to seal the electronic assembly 100. In one embodiment, the thermally-conductive material 18 is a thermal adhesive, and the adhesive properties of the material holds, secures or bonds the substrate 12 in place in the enclosure 11. In an alternate embodiment, a fasteners 17 such as one or more screws is used to attach the substrate 12 to the enclosure 11. An additional fasteners 17 can be used to attach the enclosure cover 10 to the enclosure 11.

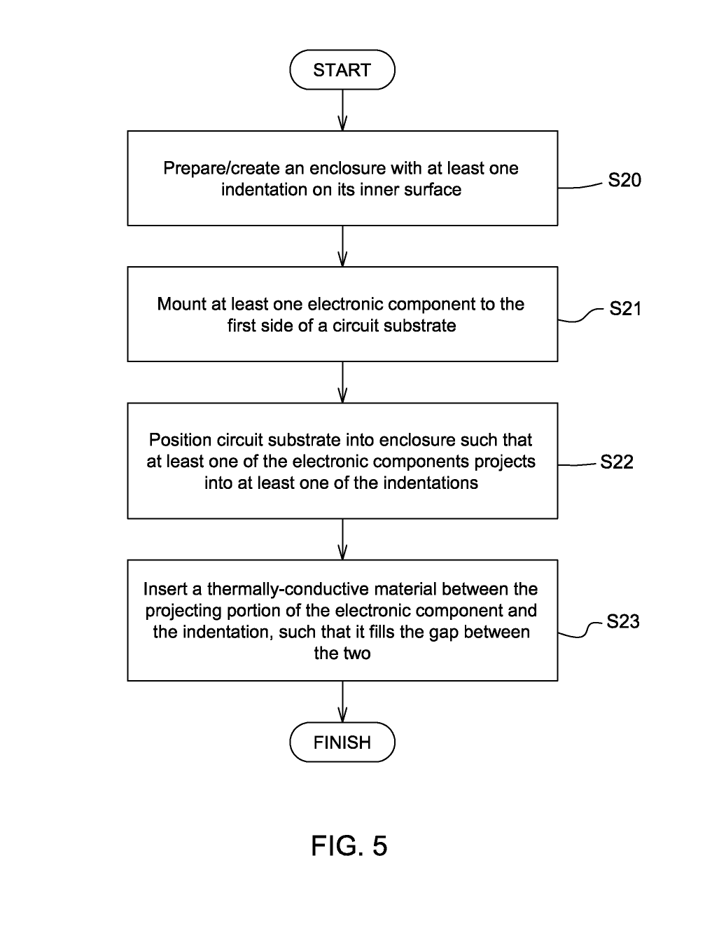

FIG. 5 is a flowchart showing a method for creating the electronic assembly 100 of FIGS. 1-4, or another electronic assembly.

In step S20, an enclosure 11 is prepared or created such that it has at least one indentation 14 on its inner surface. For example, the enclosure is stamped, molded or machined from a metal, an alloy, a plastic, a plastic composite, a filled plastic (e.g., polyester, carbon fiber, or ceramic), a polymer composite or a filled polymer (e.g., polyester, carbon fiber, or ceramic).

In step S21, at least one electronic component 13 is mounted to the first side of a circuit substrate 12. Step S21 may be executed prior to, during, or after step S20. In one embodiment, the mounting of the electronic component 13 may comprise a surface mounting technique, a through hole mounting technique or the like.

Step S21 may be executed in accordance with several procedures, which may be applied, alternately or cumulative. Under a first procedure, solder paste or flux is applied to a conductive trace or conductive pad on the substrate 12; solder portions (e.g., solder balls) are aligned on the conductive trace or conductive pad; the electronic component 13 is registered with the solder portions and conductive pads or traces; and the solder is heated (e.g., via an oven). Under a second procedure, solder paste, flux and solder, are applied and heated with a soldering gun or soldering iron. Under a third procedure, a conductive adhesive is applied to the conductive traces or conductive pads and the electronic component terminals are aligned with the conductive traces or pads.

In step S22, the circuit substrate 12 is positioned inside the enclosure 11 such that at least a portion of at least one electronic component 13 projects into at least one of the indentations 14. Although step S22 is set forth prior to step S23 in FIG. 5, step S23 may be executed prior to or simultaneously with step S22.

In step S23, a thermally-conductive material 18 is inserted, dispensed, or hydraulically forced into the indentation 14 such that it at least partially fills the gap between the inner surface of the indentation 14 and the projecting portion of the electronic component 13. For example, the thermally conductive material may partially, substantially or completely fill or surround the gap or clearance between the indentation 14 and the electronic component 13. In one embodiment, the thermally-conductive material 18 substantially fills the gap to provide an efficient thermal pathway for heat to flow from the electronic component 13 out into and through the enclosure 11 to the ambient environment.

Having described the preferred embodiment, it will become apparent that various modifications can be made without departing from the scope of the invention as defined in the accompanying claims. In particular, any thermally conductive material 18, such as a thermal pad, may be used to provide a thermal path between the electronic components 13 and the enclosure 11. An alternate thermally conductive material 18 may or may not be adhesive in nature, and the attachment of the substrate 12 to the enclosure 11 may be done by an alternate approach, such as fasteners, screws, or a snap-fit connection. Also, the enclosure cover 10 may not be necessary in all applications, or may be fastened to the enclosure 11 using various methods, including an adhesive. The electronic assembly 100 may have two or more substrates 12, one or more of which could interface with indentations 14 in different sections of the enclosure 11 or enclosure cover 10. The entire first surface of the substrate 12 may be directly bonded to the enclosure 11, or only the horizontal areas immediately surrounding the indentations 14 may be bonded. Any non-bonded portion of the first surface of the substrate 12 may be used for other electronic components requiring less or no heat dissipation.

In one embodiment, the substrate is secured or attached to the enclosure in such a manner as to minimize the stress on the solder joints holding the electronic components on the substrate. The enclosure may be associated with a heat sink for drawing heat away from high-power electronic components, such that the heat can be radiated into the open air. The recesses or pockets filled, partially, substantially or completely, with thermally conductive material support thermal conductivity to the enclosure or heat sink to prevent excessive temperature rise which can damage a component, degrade its performance, or shorten its longevity. To the extent that the components are placed in pockets associated with thermally conductive material, the mechanical stress placed on the component solder joints during periods of high vibration may be reduced or minimized to the extent that the thermally conductive material is elastic, temporarily deformable, or resilient.

What is claimed is:

1. An electronic assembly comprising:
a generally planar substrate;
an electronic component mounted to the substrate and having a projecting portion projecting above a surface of the substrate;
an enclosure having at least one side with indentations, one of the indentations positioned to receive the projecting portion of the electronic component with a clearance gap; and
a thermally-conductive material positioned between the projecting portion and the enclosure within the clearance gap.

2. The electronic assembly according to claim 1 wherein the thermally-conductive material fills at least a portion of the gap between the electronic component and the indentation when the substrate is mounted in the enclosure.

3. The electronic assembly according to claim 1 wherein the thermally-conductive material provides a thermal pathway for heat generated by the electronic component to flow out of the electronic assembly through the enclosure.

4. The electronic assembly of claim 1, wherein the thermally-conductive material is a thermal adhesive.

5. The electronic assembly of claim 4, wherein the thermal adhesive secures the substrate to the enclosure.

6. The electronic assembly of claim 1 further comprising an enclosure cover, whereas the enclosure cover attaches to the enclosure and provides an environmental seal for the substrate.

7. The electronic assembly of claim 1, wherein the thermally-conductive material prevents the movement of the electronic component in relation to the substrate, thereby reducing the amount of stress placed on solder joints holding the electronic components to the substrate.

8. The electronic assembly of claim 1, wherein the enclosure is molded from a thermally-conductive metal.

9. The electronic assembly of claim 1, wherein the enclosure further comprises one or more projecting members, the projecting members increasing the outer surface area of the enclosure, the increased outer surface area providing a more efficient means of releasing heat.

10. A method of making an electronic assembly, the method comprising:
mounting at least one electronic component to a generally planar substrate, wherein a projecting portion of the electronic component projects above the surface of the substrate;
positioning the substrate within an enclosure having at least one side with indentations, wherein one of the indentations is positioned to receive the projecting portion of the at least one electronic component with a clearance gap; and
inserting a thermally-conductive material between the projecting portion and the enclosure within the clearance gap.

11. The method according to claim 10 wherein the inserting of the thermally-conductive material further comprises filling at least a portion of the gap between the electronic component and the one indentation when the substrate is mounted in the enclosure.

12. The method according to claim 10 wherein the inserting of the thermally-conductive material further comprises providing a thermal pathway for heat generated by the electronic component to flow out of the electronic assembly through the enclosure into the ambient environment.

13. The method according to claim 10 wherein the thermally-conductive material comprises an adhesive.

14. The method according to claim 13 further comprising:
securing the substrate to the enclosure via the adhesive.

15. The method according to claim 10, further comprising:
attaching an enclosure cover to the enclosure with an intervening gasket or seal to provide environmental protection for the substrate.

16. The method according to claim 10 wherein the inserting of the thermally-conductive material between the projecting portion and the enclosure further comprises curing the thermally-conductive material to prevent movement of the electronic component in relation to the substrate and to reduce the amount of mechanical stress placed on solder joints of the electronic components.

17. The method according to claim 10 wherein the enclosure is molded from a material consisting of a metal, an alloy, a plastic, a polymer, a plastic composite, a polymer composite, a filled plastic and a filled polymer.

18. The method according to claim 10 wherein the enclosure further comprises one or more projecting members, the projecting members increasing an outer surface area of the enclosure, the increased outer surface area providing a more efficient means of radiating heat into an ambient environment.
